(19) United States
(12) Patent Application Publication
(10) Pub. No.: US 2024/0355635 A1
(43) Pub. Date: Oct. 24, 2024

(54) ETCHING APPARATUS AND ETCHING METHOD

(71) Applicant: ULVAC, INC., Chigasaki-shi (JP)

(72) Inventor: Kazuhiko TONARI, Chigasaki-shi (JP)

(21) Appl. No.: 18/761,500

(22) Filed: Jul. 2, 2024

Related U.S. Application Data
(63) Continuation of application No. 17/456,998, filed on Nov. 30, 2021.

(30) Foreign Application Priority Data
Dec. 28, 2020 (JP) 2020-219460

(51) Int. Cl. H01L 21/311

(52) U.S. Cl. CPC H01L 21/31116

(57) ABSTRACT

Provided is an etching apparatus for etching a silicon oxide film using a processing gas containing hydrogen fluoride and ammonia, including: a chamber; a gas supply unit; a water vapor supply unit; and a control unit. The chamber is configured such that a substrate having the silicon oxide film on a surface thereof can be disposed therein. The gas supply unit is configured to be capable of supplying one of the processing gas and a precursor gas of the processing gas to the chamber. The water vapor supply unit is capable of supplying water vapor to the chamber. The control unit controls the gas supply unit and the water vapor supply unit to supply the water vapor and one of the processing gas and the precursor gas to the chamber during etching processing.

### CROSS REFERENCE TO RELATED APPLICATIONS

This application is a continuation of U.S. application Ser. No. 17/456,998, filed Nov. 30, 2021; which claims the benefit of Japanese Priority Patent Application 2020-219460, filed Dec. 28, 2020, the entire contents of which are incorporated herein by reference.

### BACKGROUND

The present disclosure relates to an etching apparatus and an etching method for etching a silicon oxide film.

### SUMMARY

An apparatus and a method for etching a silicon oxide film formed on a surface of a silicon substrate have been known. For example, Japanese Patent Application Laid-open No. 2020-17661 discloses an oxide film removing apparatus that includes: a vacuum tank; a first gas supply unit that supplies a mixed gas of an ammonia gas and a nitrogen gas; and a second gas supply unit that supplies a nitrogen trifluoride gas. In this oxide film removing apparatus, a silicon oxide film is removed by an etchant (e.g., NFₓH_{y}) containing fluorine and hydrogen.

However, as disclosed in Japanese Patent Application Laid-open No. 2020-17661, in the case where a silicon oxide film is etched using an etchant containing fluorine and hydrogen, the distribution of the etching amount in the plane of the substrate is non-uniform in some cases.

In view of the circumstances as described above, it is desired to provide an etching apparatus and an etching method that are capable of improving uniformity of the etching amount of a silicon oxide film in the plane of a substrate.

### Solution to Problem

In accordance with an embodiment of the present disclosure, there is provided an etching apparatus for etching a silicon oxide film using a processing gas containing hydrogen fluoride and ammonia.

The etching apparatus includes: a chamber; a gas supply unit; a water vapor supply unit; and a control unit.

The chamber is configured such that a substrate having the silicon oxide film on a surface thereof can be disposed therein.

The gas supply unit is configured to be capable of supplying one of the processing gas and a precursor gas of the processing gas to the chamber.

The water vapor supply unit is capable of supplying water vapor to the chamber.

The control unit controls the gas supply unit and the water vapor supply unit to supply the water vapor and one of the processing gas and the precursor gas to the chamber during etching processing.

The control unit may control the water vapor supply unit to supply water vapor to the chamber at a partial pressure of 0.1 Pa or more and 100 Pa or less.

The gas supply unit may include
a first gas supply line that is capable of supplying a first precursor gas containing at least one of a gas containing hydrogen or a hydrogen radical to the chamber,
a second gas supply line that is capable of supplying a second precursor gas containing at least one of a gas containing fluorine or a fluorine radial to the chamber, and

the hydrogen fluoride may be produced by reaction of the first precursor gas and the second precursor gas with each other in the chamber.

In this case, the first gas supply line may include a radical producing unit that produces a hydrogen radical from a gas containing hydrogen.

The chamber may include
a processing chamber in which the substrate can be disposed,
a gas supply chamber connected to the gas supply unit, and
a shower plate that includes a plurality of through holes and is disposed between the gas supply chamber and the processing chamber.

In this case, the water vapor supply unit may be connected to the gas supply chamber.

In accordance with another embodiment of the present disclosure, there is provided an etching method for etching a silicon oxide film using a processing gas containing hydrogen fluoride and ammonia.

One of the processing gas and a precursor gas of the processing gas is supplied to a chamber in which a substrate having the silicon oxide film on a surface thereof is disposed.

Water vapor is supplied to the chamber.

The silicon oxide film is etched using the processing gas in the chamber to which the water vapor is supplied.

Further, water vapor may be supplied to the chamber at a partial pressure of 0.1 Pa or more and 100 Pa or less.

### Advantageous Effects of Invention

In accordance with the present disclosure, it is possible to improve uniformity of the etching amount of a silicon oxide film in the plane of a substrate.

### BRIEF DESCRIPTION OF DRAWINGS

FIG. 1 is a schematic cross-sectional view showing an etching apparatus according to a first embodiment of the present disclosure;

FIG. 2 is a flowchart describing an etching method using the etching apparatus.

FIG. 3 is a graph showing distribution of the etching amount in the plane of a substrate in etching processing according to Example of the embodiment;

FIG. 4 is a graph showing distribution of the etching amount in the plane of a substrate in etching processing according to Comparative Example of the embodiment;

FIG. 5 is a schematic cross-sectional view showing an etching apparatus according to a second embodiment of the present disclosure;

FIG. 6 is a schematic cross-sectional view showing an etching apparatus according to a third embodiment of the present disclosure;

FIG. 7 is a schematic cross-sectional view showing an etching apparatus according to a fourth embodiment of the present disclosure;

FIG. 8 is a schematic cross-sectional view showing an etching apparatus according to a fifth embodiment of the present disclosure; and

FIG. 9 is a schematic cross-sectional view showing an etching apparatus according to a sixth embodiment of the present disclosure.

### DETAILED DESCRIPTION OF EMBODIMENTS

### Overview of Present Disclosure

The present disclosure relates to an etching apparatus and an etching method for etching a silicon oxide film using a processing gas containing hydrogen fluoride (HF) and ammonia (NH₃).

The processing gas is supplied into a chamber in which a substrate having a silicon oxide film on a surface thereof is disposed. By the processing gas, HF and NH₃ react with each other as follows.

HF+NH₃->NH₄F (1)

As a result, ammonia fluoride (NH₄F) is produced. The produced NH₄F reacts with the silicon oxide film on the surface of the substrate. This reaction is represented by the following formula (2).

SiO₂+6NH₄F->(NH₄)₂SiF₆+2H₂O+4NH₃ (2)

In this way, NH₄F and SiO₂ of the silicon oxide film react with each other to produce a reaction product ((NH₄)₂SiF₆) formed of an ammonia complex that is easily thermally-decomposed at 100 to 200° C. on the surface of the substrate. As a result, the silicon oxide film is etched.

In the reaction represented by the formula (2), H₂O and NH₃ together with the reaction product described above are produced. Since this H₂O is produced on the surface of the substrate, the distribution amount of H₂O can be less at the periphery than at the center of the substrate, for example.

In accordance with the findings of the present inventors, it is conceivable that the reaction represented by the formula (2) occurs mainly due to the attack of fluorine (F⁻) ionized from NH₄F on SiO₂ and H₂O is involved in this ionization of fluorine. For this reason, it is conceivable that the deviation of the etching amount in the plane of the substrate occurs due to the deviation of the distribution of H₂O on the surface of the substrate.

In this regard, the present disclosure is characterized in that water vapor (H₂O gas) is supplied in to the chamber in addition to the processing gas in the etching processing. As a result, as described below in detail, the deviation of the distribution of H₂O on the surface of the substrate is suppressed and the uniformity of the etching amount in the plane of the substrate is improved.

Note that on the surface of the substrate, some of supplied or produced H₂O can become a liquid. For this reason, an H₂O gas in a gas state is referred to as “water vapor” and H₂O in a gas or liquid state is referred to as “H₂O”.

Hereinafter, embodiments of the present disclosure will be described with reference to the drawings. An X-axis, a Y-axis, and a Z-axis described in the drawings indicate directions perpendicular to each other.

### First Embodiment

### [Configuration of Etching Apparatus]

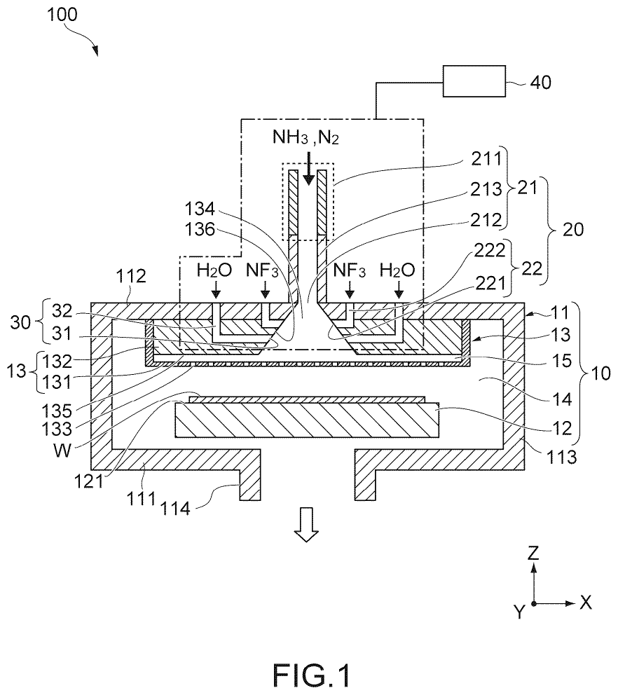

FIG. 1 is a schematic cross-sectional view showing an etching apparatus 100 according to a first embodiment of the present disclosure.

As shown in FIG. 1, the etching apparatus 100 includes a chamber 10, a gas supply unit 20, a water vapor supply unit 30, and a control unit 40. The etching apparatus 100 is a dry etching apparatus for etching a silicon oxide film using a processing gas containing HF and NH₃, e.g., a remote plasma etching apparatus that is capable of producing a radical outside of the chamber 10.

The chamber 10 is configured such that a substrate W having a silicon oxide film on a surface thereof can be disposed therein. In this embodiment, the chamber 10 includes a chamber body 11 and a substrate support portion 12.

The chamber body 11 includes, for example, a vacuum tank formed of a metal. The chamber body 11 includes a bottom portion 111, a top plate 112, and a side wall 113. The chamber body 11 may be configured such that the top plate 112 can be separated or the bottom portion 111, the top plate 112, and the side wall 113 are integrated. Further, the chamber body 11 includes an exhaust port 114 connected to a vacuum pump, and can be exhausted from the exhaust port 114. The exhaust port 114 is disposed in, for example, the bottom portion 111.

The top plate 112 is disposed so as to face the bottom portion 111 in the Z-axis direction. In this embodiment, a gas head 13 described below is attached to the top plate 112. The top plate 112 may include, for example, an opening that is connected to a first gas supply line 21 described below and is opened in the Z-axis direction.

The substrate support portion 12 includes, for example, a stage on which the substrate W can be disposed. The substrate support portion 12 has a support surface 121 on which the substrate W is to be disposed. The support surface 121 is disposed so as to face the top plate 112 in the Z-axis direction, for example.

In this embodiment, the inside of the chamber 10 is partitioned by the gas head 13 including a shower plate 131. That is, the chamber 10 further includes a processing chamber 14 in which the substrate W can be disposed, a gas supply chamber 15 connected to the gas supply unit 20 described below, and the shower plate 131 disposed between the processing chamber 14 and the gas supply chamber 15. In this embodiment, the gas supply chamber 15 is disposed so as to face the support surface 121 in the Z-axis direction.

In this embodiment, the shower plate 131 includes part of the gas head 13. The gas head 13 includes the shower plate 131 and a head body 132.

The shower plate 131 includes a plurality of through holes 133. The plurality of through holes 133 functions as a gas ejection hole for ejecting a gas from the gas supply chamber 15 toward the processing chamber 14. The shower plate 131 is disposed such that, for example, the plurality of through holes 133 faces the support surface 121 in the Z-axis direction.

The head body 132 is disposed between the shower plate 131 and the top plate 112. The internal space of the gas head 13 formed between the head body 132 and the shower plate 131 forms the gas supply chamber 15. The head body 132 includes, for example, an opening 134 that is connected to the first gas supply line 21 described below and is opened in the Z-axis direction, a plate facing surface 135 that faces the shower plate 131, and a circular tapered surface 136 that connects the plate facing surface 135 and the opening 134 to each other and is disposed around the opening 134.

The gas supply unit 20 is configured to be capable of supplying a processing gas or a precursor gas of the processing gas to the chamber 10.

The processing gas is a reactive gas containing HF and NH₃ as described above.

The precursor gas is a gas containing a precursor of the processing gas.

The gas supply unit 20 may supply an HF gas and an NH₃ gas to the chamber 10. Alternatively, the gas supply unit 20 may supply the precursor gas to the chamber 10. In the latter case, for example, the precursor gas supplied by the gas supply unit 20 reacts in the chamber 10 to produce a processing gas.

Note that the processing gas and the precursor gas may contain not only a normal gas but an atom in a radical state.

In this embodiment, the gas supply unit 20 includes a first gas supply line 21 and a second gas supply line 22.

The first gas supply line 21 is configured to be capable of supplying, to the chamber 10, a first precursor gas containing at least one of a gas containing hydrogen or a hydrogen radical. The “gas containing hydrogen” represents a hydrogen gas (H₂) that is not in a radical state or a gas containing a hydrogen compound, and the “hydrogen radical” represents a hydrogen gas (H*) in a radical state. The first precursor gas contains, for example, H* and an NH₃ gas.

The first gas supply line 21 includes a radical producing unit 211 that produces a hydrogen radical from, for example, a gas containing hydrogen, a first supply port 212 that is opened to the chamber 10, and a first pipe 213 that connects the radical producing unit 211 and the first supply port 212 to each other.

The radical producing unit 211 includes a remoter plasma source. Specifically, the radical producing unit 211 may include a microwave plasma source, a high-frequency plasma source, a capacitively coupled plasma source, an inductively coupled plasma source, or the like. In this embodiment, the radical producing unit 211 includes a microwave plasma source including, for example, a discharge tube and a microwave source. A gas containing hydrogen is introduced into the discharge tube from a gas source (not shown). The discharge tube is connected to the first pipe 213. The microwave source applies, for example, an excited microwave to the discharge tube. The “gas containing hydrogen” to be introduced into the radical producing unit 211 is, for example, a mixed gas of an NH₃ gas and a nitrogen (N₂) gas that is a carrier gas.

In this embodiment, the first supply port 212 is opened to the gas supply chamber 15. The first supply port 212 is opened at, for example, a position facing the shower plate 131 in the Z-axis direction and is connected to the opening 134 of the head body 132.

The second gas supply line 22 is configured to be capable of supplying, to the chamber 10, a second precursor gas containing at least one of a gas containing fluorine or a fluorine radial. The “gas containing fluorine” represents a gas containing a fluorine gas (F₂) that is not in a radical state or a gas containing fluorine compound, and the “fluorine radial” represents a fluorine gas (F*) in a radical state. The second precursor gas is, for example, a nitric trifluoride (NF₃) gas.

The second gas supply line 22 includes, for example, a second supply port 221 that is opened to the chamber 10, and a second pipe 222 connected to the second supply port 221.

In this embodiment, the second supply port 221 is opened to the gas supply chamber 15. The second supply port 221 is opened to, for example, the tapered surface 136 of the head body 132. The second gas supply line 22 may include a plurality of second supply ports 221, and the second supply ports 221 may be disposed on the tapered surface 136 so as to surround the first supply port 212.

In this embodiment, the first gas supply line 21 and the second gas supply line 22 are connected to the gas supply chamber 15. As a result, the first precursor gas and the second precursor gas react with each other in the gas supply chamber 15 to produce the above-mentioned processing gas for etching, and the processing gas diffuses in the gas supply chamber 15. Thus, the processing gas is uniformly supplied onto the substrate W via the shower plate 131.

The water vapor supply unit 30 is configured such that water vapor can be supplied to the chamber 10. The water vapor functions as an etching promotion gas. When the water vapor supply unit 30 supplies water vapor to the chamber 10, the water vapor is supplied into the whole plane of the substrate W and thus, the deviation of the distribution of H₂O in the plane of the substrate W is suppressed. Therefore, the uniformity of the etching amount in the plane of the substrate W is improved.

The water vapor supply unit 30 includes, for example, a third supply port 31 that is opened to the chamber 10, and a third pipe 32 connected to the third supply port 31.

In this embodiment, the third supply port 31 is opened to the gas supply chamber 15. In the example shown in FIG. 1, the third supply port 31 is opened to the tapered surface 136 of the head body 132. The water vapor supply unit 30 may include a plurality of third supply ports 31, and the third supply ports 31 may be disposed on the tapered surface 136 so as to surround the first supply port 212. In the example shown in FIG. 1, the third supply port 31 is disposed on the downstream side of the second supply port 221.

For example, a vaporizer that produces water vapor from liquid water may be connected to the third pipe 32.

In this embodiment, the water vapor supply unit 30 is the gas supply chamber 15, and thus, water vapor diffuses in the gas supply chamber 15. As a result, water vapor is uniformly supplied onto the substrate W via the shower plate 131. Therefore, the deviation of the distribution of H₂O in the plane of the substrate W is more effectively suppressed, and the uniformity of the etching amount in the plane of the substrate W is further improved.

The control unit 40 controls the gas supply unit 20 and the water vapor supply unit 30 to supply a processing gas and water vapor or a precursor gas and water vapor to the chamber 10 during etching processing.

The control unit 40 is realized by hardware elements used in a computer, such as a CPU (Central Processing Unit), a RAM (Random Access Memory), and a ROM (Read Only Memory), and necessary software. The control unit 40 only needs to control at least the gas supply unit 20 and the water vapor supply unit 30, but may be configured to control the whole etching apparatus 100.

### [Etching Method]

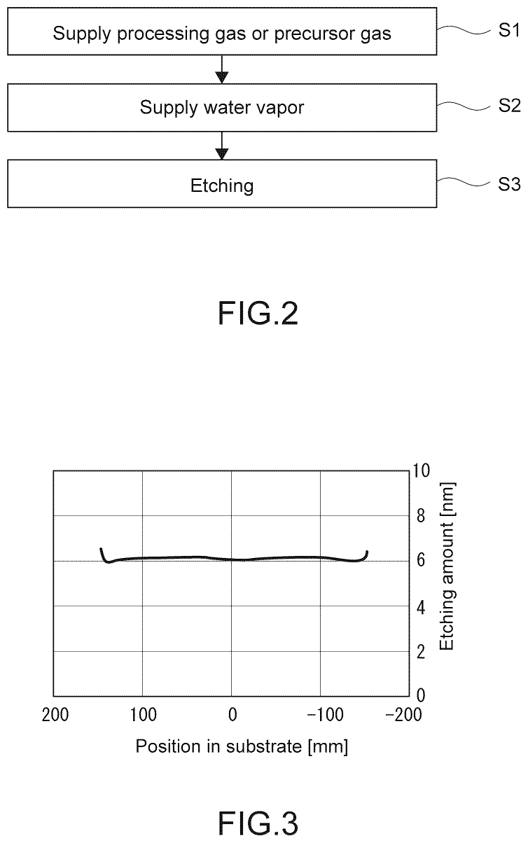

FIG. 2 is a flowchart describing an etching method according to this embodiment.

An etching method using the etching apparatus 100 having the configuration described above will be described below.

First, as shown in FIG. 1, the substrate W having a silicon oxide film on a surface thereof is disposed in the chamber 10. The substrate W is, for example, a silicon substrate. The silicon oxide film may be a natural oxide film or a film formed by oxidation processing or the like. The pressure in the chamber 10 is reduced to a predetermined pressure.

As shown in FIG. 2, the gas supply unit 20 then supplies, to the chamber 10 in which the substrate W is disposed, a processing gas containing HF and NH₃ or a precursor gas of the processing gas (Step S1). That is, the control unit 40 controls the gas supply unit 20 to supply a processing gas or a precursor gas.

In Step S1, for example, the control unit 40 controls the first gas supply line 21 to supply, to the chamber 10, a first precursor gas containing at least one of a gas containing hydrogen or a hydrogen radical.

In the first gas supply line 21, for example, a mixed gas of an NH₃ gas and an N₂ gas is introduced into the radical producing unit 211 as a raw material gas. In the radical producing unit 211, part of the NH₃ gas and the N₂ gas becomes a radical state to produce H* and N*. As a result, the first precursor gas contains, for example, an NH₃ gas, H*, an N₂ gas, and N*.

Further, for example, the control unit 40 controls the second gas supply line 22 to supply a second precursor gas containing fluorine or a fluorine radial to the chamber 10. The second precursor gas is, for example, an NF₃ gas.

In this embodiment, the first precursor gas and the second precursor gas are mixed with each other in the gas supply chamber 15 of the chamber 10, and thus, the reaction represented by the following formula (3) occurs.

H*+NF₃->HF+NF₂ (3)

As a result, in the gas supply chamber 15, a processing gas containing HF and NH₃ that has not become a radical state in the first gas supply line 21 is produced. The HF produced in the reaction described above is in a highly-reactive state.

Meanwhile, as shown in FIG. 2, the water vapor supply unit 30 supplies water vapor to the chamber (Step S2). That is, the control unit 40 controls the water vapor supply unit 30 to supply water vapor. In this embodiment, water vapor is supplied to the gas supply chamber 15 and is supplied to the processing chamber 14 via the shower plate 131. Suitable conditions and the like in Step S2 will be described below.

Subsequently, as shown in FIG. 2, a silicon oxide film is etched using a processing gas containing HF and NH₃ in the chamber 10 to which water vapor is supplied (StepS3). In this Step, the control unit 40 controls the gas supply unit 20 and the water vapor supply unit 30 to supply a processing gas and water vapor or a precursor gas and water vapor to the chamber 10 during etching processing.

In the gas supply chamber 15, the reaction represented by the above-mentioned formula (1) occurs by HF and NH₃ contained in the processing gas and ammonia fluoride (NH₄F) is produced. The formula (1) is mentioned again.

HF+NH₃->NH₄F (1)

The produced NH₄F is supplied to the processing chamber 14 via the shower plate 131, for example.

The NH₄F supplied to the processing chamber 14 reacts with the silicon oxide film on the surface of the substrate W. The above-mentioned formula (2) occurs due to the reaction of NH₄F and SiO₂ of the silicon oxide film with each other, and a reaction product ((NH₄)₂SiF₆) formed of an ammonia complex is produced on the surface of the substrate W. The formula (2) is mentioned again.

SiO₂+6NH₄F->(NH₄)₂SiF₆+2H₂O+4NH₃ (2)

The “etching the silicon oxide film” in this embodiment represents that the reaction product described above is produced. This reaction product is thermally decomposed and removed by subsequently heating the substrate W at a predetermined temperature (e.g., 100 to 200 ° C.). The reaction product may be removed in the same chamber 10 or in a different chamber.

In Step S3, from the viewpoint of efficiently producing a reaction product, the temperature of the substrate W may be maintained at −5° C. or more and 50° C. or less.

The H₂O produced in the formula (2) is produced on the surface of the substrate W together with the reaction product, and thus, is not produced outside of the substrate W. That is, the distribution amount of H₂O from this reaction is less at the periphery than at the center of the substrate W. As described above, it is conceivable that H₂O is involved in the etching of the silicon oxide film by NH₄F. In the case where the deviation of the distribution of H₂O on the surface of the substrate W occurs, the deviation of the amount of produced reaction products occurs, and thus, the deviation of the etching amount in the plane of the substrate W can occur.

In this regard, in this embodiment, the etching processing described above is performed in the chamber 10 to which water vapor is supplied by the water vapor supply unit 30. As a result, the water vapor diffuses in the chamber 10 during the etching processing and is evenly supplied into the whole plane of the substrate W. Therefore, the reaction represented by the formula (2) described above is promoted uniformly in the plane of the substrate W. As a result, the deviation of the amount of produced reaction products is suppressed in the plane of the substrate W, and the uniformity of the etching amount is improved.

In Step S2, the control unit 40 controls the water vapor supply unit 30 to supply water vapor to the chamber 10 at a partial pressure of, for example, 0.1 Pa or more and 100 Pa or less. As a result, water vapor enough to diffuse in the whole plane of the substrate W is supplied to the chamber 10, and the deviation of the distribution of H₂O in the plane of the substrate W is more effectively eliminated. Therefore, the uniformity of the etching amount in the plane of the substrate W is further improved.

Note that in the etching processing in Step S3, the pressure in the chamber 10 can be made, for example, 10 Pa or more and 1000 Pa or less, and can be 10 Pa or more and 500 Pa or less.

In Step S2, the control unit 40 may control the water vapor supply unit 30 to start supplying water vapor simultaneously with the supply of a gas by the gas supply unit 20. As a result, water vapor diffuses in the whole plane of the substrate W simultaneously with the start of etching processing, and the deviation of the etching amount in the plane of the substrate W is more reliably suppressed.

### Example

The operation and effect in this embodiment will be described below by way of Example and Comparative Example.

As Example, an etching apparatus including a water vapor supply unit as shown in FIG. 1 was used to etch a silicon substrate having a silicon oxide on a surface thereof. The silicon substrate was a circular substrate having a radius of approximately 150 mm.

A mixed gas of an NH₃ gas and an N₂ gas was introduced into a first gas supply line as a raw material gas. The frequency of the microwave in a radical producing unit was set to 2.45 GHz and the discharge power was set to 1800 kW.

NF₃ was introduced into a second gas supply line.

Water vapor was introduced into a water vapor supply unit.

The pressure in the chamber during the etching processing was adjusted to approximately 500 Pa. The partial pressures of the NH₃ gas, the N₂ gas, the NF₃ gas, and the water vapor were respectively adjusted to approximately 56 Pa, approximately 430 Pa, approximately 12 Pa, and approximately 2 Pa.

The temperature of the substrate during the etching processing was set to approximately 20 ° C.

As Comparative Example, an etching apparatus that does not include a water vapor supply unit was used to etch a silicon substrate having a silicon oxide on a surface thereof without supplying water vapor into a chamber.

The same gas as that in Example was introduced into a first gas supply line and a second gas supply line. The discharging condition in a radical producing unit and the temperature of the substrate during the etching processing were also set to be the same as those in Example.

The pressure in the chamber during the etching processing was adjusted to approximately 500 Pa. The partial pressures of the NH₃ gas, the N₂ gas, and the NF₃ gas were respectively adjusted to approximately 56 Pa, approximately 432 Pa, and approximately 12 Pa.

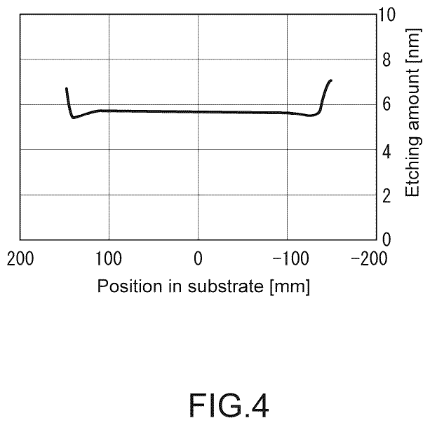

FIG. 3 and FIG. 4 are respectively graphs showing the distribution of the etching amount in the plane of the substrate during the etching processing in Example and Comparative Example. The horizontal axis indicates the position (mm) in the substrate, and the vertical axis indicates the etching amount (nm). FIG. 3 shows the result in Example, and FIG. 4 shows the result in Comparative Example.

As shown in FIG. 4, in the etching processing in Comparative Example in which water vapor is not supplied, the etching amount greatly changed at the periphery of the substrate.

Meanwhile, as shown in FIG. 3, in the etching processing in Example in which water vapor is supplied, the change in the etching amount at the periphery of the substrate was suppressed as compared with the result in Comparative Example.

From these results, it was found that the uniformity of the etching amount in the surface of the substrate was improved by supplying water vapor into the chamber when etching the silicon oxide film using the processing gas containing HF and NH₃.

### Second Embodiment

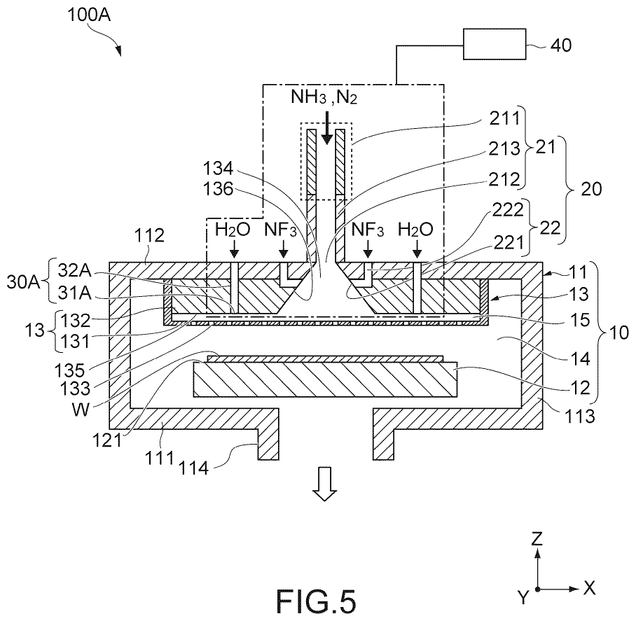

FIG. 5 is a schematic cross-sectional view showing an etching apparatus 100A according to a second embodiment of the present disclosure.

As shown in the figure, the etching apparatus 100A includes the chamber 10, the gas supply unit 20, and the control unit 40 that are similar to those in the first embodiment, but includes a water vapor supply unit 30A different from that in the first embodiment.

In the following embodiments, the same components as those in the above-mentioned first embodiment are denoted by the same reference symbols, description thereof is omitted, and different portions will be mainly described.

The water vapor supply unit 30A includes, for example, a third supply port 31A opened to the chamber 10, and a third pipe 32A connected to the third supply port 31A.

The third supply port 31A is opened to, for example, the plate facing surface 135 of the head body 132. The water vapor supply unit 30A includes a plurality of third supply ports 31A in the example shown in FIG. 5, but may include a single third supply port 31A.

As a result, water vapor diffuses in the gas supply chamber 15, and is uniformly supplied into the whole place of the substrate W via the shower plate 131. Therefore, the uniformity of the etching amount in the plane of the substrate W is sufficiently improved.

### Third Embodiment

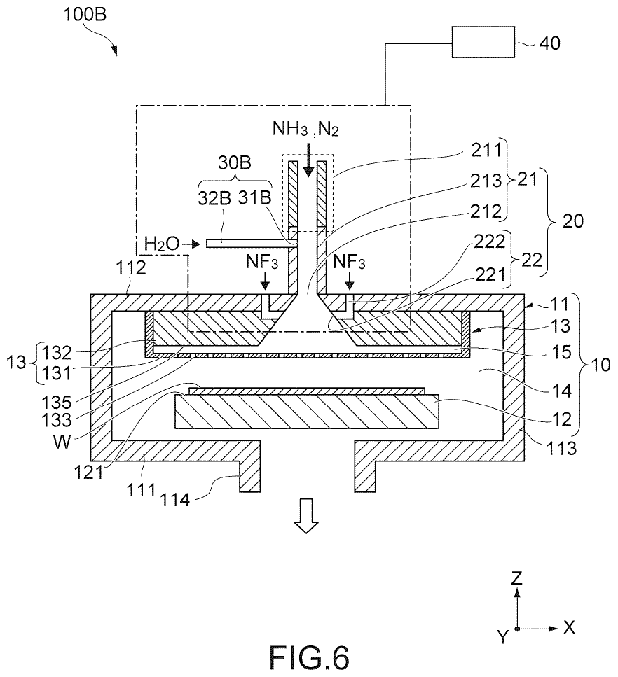

FIG. 6 is a schematic cross-sectional view showing an etching apparatus 100B according to a third embodiment of the present disclosure.

As shown in the figure, the etching apparatus 100B includes the chamber 10, the gas supply unit 20, and the control unit 40 that are similar to those in the first embodiment, but includes a water vapor supply unit 30B different from that in the first embodiment.

As shown in FIG. 6, the water vapor supply unit 30B includes a third supply port 31B opened to the first pipe 213, and a third pipe 32B connected to the third supply port 31B. In this embodiment, water vapor is supplied to the chamber 10 through the third pipe 32B and part of the first pipe 213 of the first gas supply line 21.

As a result, water vapor is supplied from the upstream of the gas supply chamber 15, and can more uniformly diffuse in the gas supply chamber 15. Therefore, water vapor is more uniformly supplied into the whole plane of the substrate W via the shower plate 131, and the uniformity of the etching amount in the plane of the substrate W is further improved.

### Fourth Embodiment

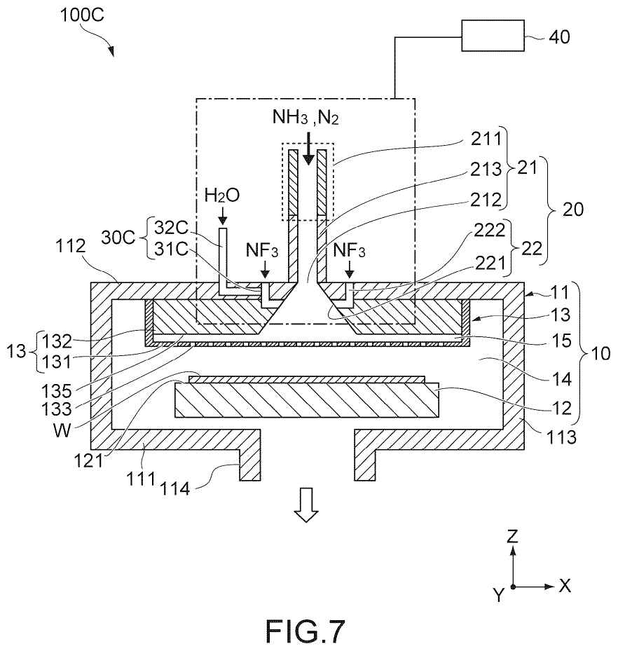

FIG. 7 is a schematic cross-sectional view showing an etching apparatus 100C according to a fourth embodiment of the present disclosure.

As shown in the figure, the etching apparatus 100C includes the chamber 10, the gas supply unit 20, and the control unit 40 that are similar to those in the first embodiment, but includes a water vapor supply unit 30C different from that in the first embodiment.

As shown in FIG. 7, the water vapor supply unit 30C includes a third supply port 31C opened to the second pipe 222, and a third pipe 32C connected to the third supply port 31C. That is, in this embodiment, water vapor is supplied to the chamber 10 through the third pipe 32C and part of the second pipe 222 of the second gas supply line 22. In the example shown in FIG. 7, the water vapor supply unit 30C includes a single third supply port 31C, but may include a plurality of third supply ports 31C connected to a plurality of second pipes 222.

Also in this case, water vapor is supplied from the upstream of the gas supply chamber 15, and can more uniformly diffuse in the gas supply chamber 15. Therefore, water vapor is more uniformly supplied into the whole plane of the substrate W via the shower plate 131, and the uniformity of the etching amount in the plane of the substrate W is further improved.

### Fifth Embodiment

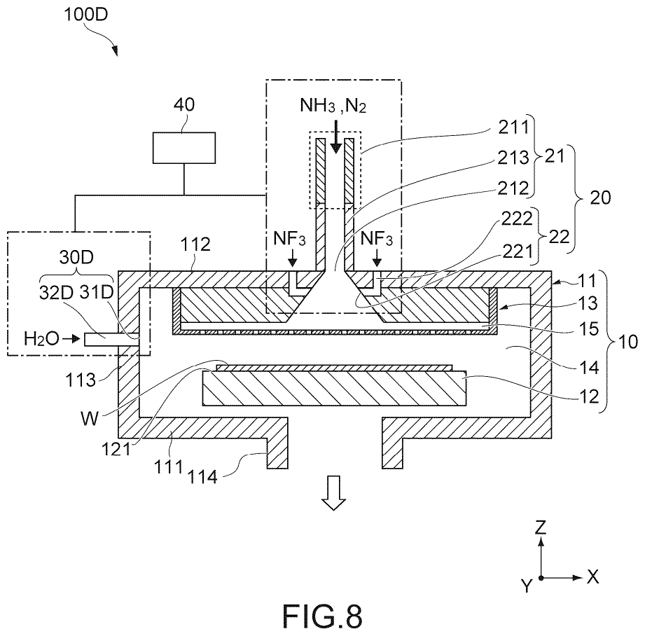

FIG. 8 is a schematic cross-sectional view showing an etching apparatus 100D according to a fifth embodiment of the present disclosure.

As shown in the figure, the etching apparatus 100D includes the chamber 10, the gas supply unit 20, and the control unit 40 that are similar to those in the first embodiment, but includes a water vapor supply unit 30D different from that in the first embodiment.

As shown in FIG. 8, the water vapor supply unit 30D includes, for example, a third supply port 31D opened to the processing chamber 14 of the chamber 10, and a third pipe 32D connected to the third supply port 31D.

As shown in FIG. 8, the third supply port 31D is opened to, for example, the side wall 113 of the chamber 10. The water vapor supply unit 30D includes a single third supply port 31D in the example shown in FIG. 8, but may include a plurality of third supply ports 31D.

Also in this case, water vapor is supplied to the processing chamber 14 of the chamber 10, and can more uniformly diffuse in the processing chamber 14. Therefore, water vapor can uniformly diffuse in the whole plane of the substrate W, and the uniformity of the etching amount in the plane of the substrate W is improved.

### Sixth Embodiment

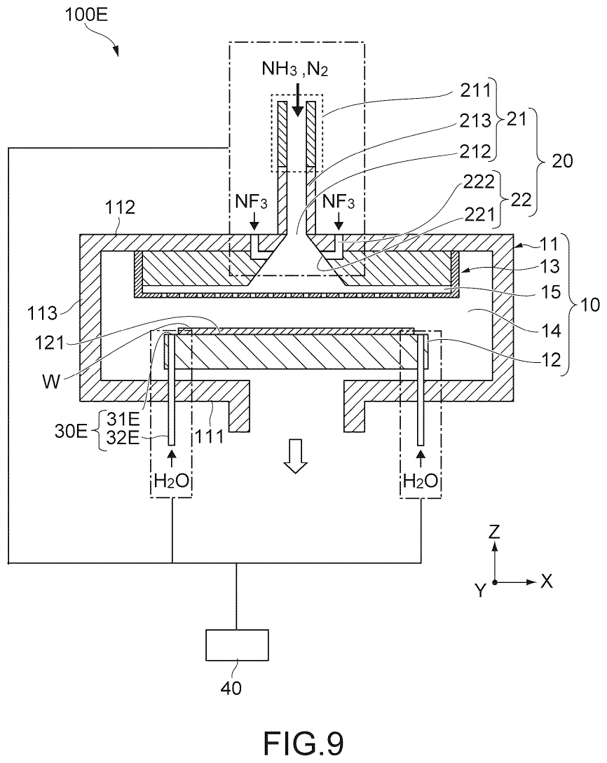

FIG. 9 is a schematic cross-sectional view showing an etching apparatus 100E according to a sixth embodiment of the present disclosure.

As shown in the figure, the etching apparatus 100E includes the chamber 10, the gas supply unit 20, and the control unit 40 that are similar to those in the first embodiment, but includes a water vapor supply unit 30E different from that in the first embodiment.

As shown in FIG. 9, the water vapor supply unit 30E includes, for example, a third supply port 31E opened to the processing chamber 14 of the chamber 10, and a third pipe 32E connected to the third supply port 31E.

As shown in FIG. 9, the third supply port 31E is opened to the support surface 121 of the substrate support portion 12. In FIG. 9, the water vapor supply unit 30E includes plurality of third supply ports 31E. The plurality of third supply ports 31E is disposed, for example, along the periphery of the support surface 121.

As a result, it is possible to more directly supply water vapor to the periphery of the substrate W having a small distribution amount of H₂O produced with the production of the reaction product ((NH₄)₂SiF₆). Therefore, the uniformity of the etching amount in the plane of the substrate W is more reliably improved.

### OTHER EMBODIMENTS

Although the embodiments of the present disclosure have been described above, the present disclosure is not limited to the above-mentioned embodiments, and various modifications can be made without departing from the essence of the present disclosure.

The chamber 10 is not limited to the above-mentioned configuration.

For example, the gas supply chamber 15 is not necessarily need to be disposed so as to face the support surface 121 in the Z-axis direction, and may be disposed on the side of the support surface 121, i.e., along the side wall 113 of the chamber 10. In this case, the shower plate 131 may be disposed such that the plurality of through holes 133 extends along the X-axis direction or the Y-axis direction.

Alternatively, the chamber 10 does not necessarily need to include the gas head 13, and the processing chamber 14 and the gas supply chamber 15 may be partitioned by only the shower plate 131.

Further, in the chamber 10, the processing chamber 14 and the gas supply chamber 15 are not necessarily need to be partitioned, and the inside of the whole chamber 10 may be configured as the processing chamber 14. In this case, the gas supply unit 20 may be directly connected to the top plate, the side wall, or the like of the processing chamber 14.

Further, also the first gas supply line 21 and the second gas supply line 22 of the gas supply unit 20 are not limited to the above-mentioned configuration, and may be connected to positions different from those in the illustrated example.

Alternatively, the gas supply unit 20 is not limited to the configuration in which the precursor gas of the processing gas is supplied to the chamber 10. For example, a processing gas containing HF and NH₃ may be produced outside of the chamber 10, and the produced processing gas may be supplied to the chamber 10.

What is claimed is:

1. An etching method for etching a silicon oxide film using a processing gas containing hydrogen fluoride and ammonia and water vapor, comprising:
supplying one of the processing gas and a precursor gas of the processing gas to a chamber in which a substrate having the silicon oxide film on a surface thereof is disposed;
supplying the water vapor to the whole of a surface of the substrate in the chamber; and
etching the silicon oxide film using the processing gas in the chamber to which the water vapor is supplied, wherein
the supplying one of the processing gas and the precursor gas of the processing gas to the chamber includes
supplying a first precursor gas containing a hydrogen radical to the chamber from a first gas supply line,
supplying a second precursor gas containing a gas containing fluorine to the chamber from a second gas supply line, and
producing the hydrogen fluoride by reaction of the first precursor gas and the second precursor gas with each other in the chamber.

2. The etching method according to claim 1, wherein
water vapor is supplied to the chamber at a partial pressure of 0.1 Pa or more and 100 Pa or less.

3. The etching method according to claim 1, wherein
the chamber includes
a processing chamber in which the substrate is disposed,
a gas supply chamber connected to the first gas supply line and the second gas supply line, and
a shower plate that includes a plurality of through holes and is disposed between the gas supply chamber and the processing chamber,
the processing gas is supplied to the substrate in the processing chamber from the gas supply chamber through the shower plate.

4. The etching method according to claim 3, wherein
the water vapor is supplied to the gas supply chamber.

5. The etching method according to claim 3, wherein
the water vapor is supplied to the processing chamber.
